(19) United States
(12) Patent Application Publication
(10) Pub. No.: US 2014/0203323 A1
(43) Pub. Date: Jul. 24, 2014

(54) PRIMER COMPOSITION AND OPTICAL SEMICONDUCTOR APPARATUS USING SAME

(71) Applicant: SHIN-ETSU CHEMICAL CO., LTD., Tokyo (JP)

(72) Inventor: Toshiyuki OZAI, Takasaki (JP)

(73) Assignee: SHIN-ETSU CHEMICAL CO., LTD., Tokyo (JP)

(21) Appl. No.: 14/145,031

(22) Filed: Dec. 31, 2013

(30) Foreign Application Priority Data
Jan. 18, 2013 (JP) 2013-007387
Feb. 6, 2013 (JP) 2013-021399

(51) Int. Cl. H01L 33/56; H01L 23/29

(52) U.S. Cl. CPC H01L 33/56; H01L 23/296
USPC 257/100; 524/506; 257/791

(57) ABSTRACT

The invention provides a primer composition which adheres a substrate mounting an optical semiconductor device and a cured material of an addition reaction curing silicone composition that encapsulates the optical semiconductor device, includes (A) silazane compound or polysilazane compounds that has one or more silazane bonds in the molecule, (B) acrylic resin containing either one or both of acrylate ester and methacrylate ester that contains one or more SiH groups in the molecule, and (C) solvent. There can be provided a primer composition in which the adhesion between a substrate mounting an optical semiconductor device and a cured material of an addition reaction curing silicone composition that encapsulates the optical semiconductor device can be improved, the corrosion of a metal electrode on the substrate can be prevented, and the heat resistance and flexibility of a primer can be improved.

### BACKGROUND OF THE INVENTION

1. Field of the Invention

The present invention relates to a primer composition which adheres a substrate mounting an optical semiconductor device adheres to a cured material of an addition reaction curing silicone composition that encapsulates the optical semiconductor device, and an optical semiconductor apparatus using the composition.

2. Description of the Related Art

Light-emitting diode (LED) lamp known as an optical semiconductor apparatus has LED as an optical semiconductor device, and is configured by encapsulating the LED mounted on a substrate with an encapsulant including a transparent resin. As the encapsulant encapsulating the LED, an epoxy resin-based composition has been generally used so far. However, when an epoxy resin-based encapsulant is used, cracking and yellowing are likely to be caused by an increase in heat value and a decrease in the wavelength of light that are accompanied by miniaturization of a semiconductor package and increased brightness of LED in recent years. The reliability may decrease.

In terms of excellent heat resistance, a silicone composition has been used as an encapsulant (e.g., Patent Document 1). In particular, an addition reaction curing silicone composition is suitable for an encapsulant for LED since it is cured by heating in a short time and has good productivity (e.g., Patent Document 2). However, the adhesion between a substrate mounting LED and an encapsulant including a cured material of the addition reaction curing silicone composition is not sufficient.

On the other hand, a polyphthalamide resin has been often used as a substrate mounting LED since the mechanical strength is excellent. Therefore, a primer useful for the resin has been developed (e.g., Patent Document 3). However, in LED that requires a high light amount, the heat resistance of polyphthalamide resin is not sufficient, and the resin is tarnished. Recently, ceramic typified by alumina having more excellent heat resistance than the polyphthalamide resin has been often used for a substrate. The substrate made of alumina ceramic is easily delaminated from the cured material of the addition reaction curing silicone composition.

Since a silicone composition generally has excellent gas permeability, it is likely to be affected by the outside environment. When LED lamp is exposed to sulfur compounds, exhaust gas, or the like in the air, the sulfur compounds or the like permeates a cured material of the silicone composition, and a metal electrode, especially an Ag electrode on a substrate encapsulated by the cured material is corroded with time and turns black. As a countermeasure for this situation, a primer in which a polymer of acrylate ester, a copolymer with an acrylate ester, a copolymer with a methacrylate ester, a copolymer of an acrylate ester and a methacrylate ester containing a SiH group (Patent Document 4), or a polysilazane compound (Patent Document 5) is used to suppress blackening has been developed. However, when an acryl polymer containing a SiH group is used, the heat resistance of a primer film is insufficient. The resin deteriorates around a recent semiconductor device in which a high current flows. In contrast, a polysilazane compound has excellent heat resistance, but a film of polysilazane is hard. Therefore, when the compound is applied to a mounted substrate on which many optical semiconductor devices referred to as a multichip are mounted, the film is cracked.

As conventional techniques associated with the present invention, the above-described documents and the following documents (Patent Documents 6 to 8) can be exemplified.

### PRIOR ART DOCUMENTS

### Patent Documents

Patent Document 1: Japanese Patent Laid-Open Publication No. 2000-198930
Patent Document 2: Japanese Patent Laid-Open Publication No. 2004-292714
Patent Document 3: Japanese Patent Laid-Open Publication No. 2008-179694
Patent Document 4: Japanese Patent Laid-Open Publication No. 2010-168496
Patent Document 5: Japanese Patent Laid-Open Publication No. 2012-144652
Patent Document 6: Japanese Patent Laid-Open Publication No. 2004-339450
Patent Document 7: Japanese Patent Laid-Open Publication No. 2005-093724
Patent Document 8: Japanese Patent Laid-Open Publication No. 2007-246803

### SUMMARY OF THE INVENTION

The present invention was made in view of the above situation, and has an object to provide a primer composition in which the adhesion between a substrate mounting an optical semiconductor device and a cured material of an addition reaction curing silicone composition that encapsulates the optical semiconductor device can be improved, the corrosion of a metal electrode formed on the substrate can be prevented, and the heat resistance and flexibility of a primer itself can be improved.

In order to achieve the object, the present invention provides a primer composition which adheres a substrate mounting an optical semiconductor device and a cured material of an addition reaction curing silicone composition that encapsulates the optical semiconductor device, including (A) silazane compound or polysilazane compound that has one or more silazane bonds in the molecule, (B) acrylic resin containing either one or both of acrylate ester and methacrylate ester that contains one or more SiH groups in the molecule, and (C) solvent.

According to such a primer composition, the adhesion between the substrate mounting the optical semiconductor device and the cured material of the addition reaction curing silicone composition that encapsulates the optical semiconductor device can be improved, the corrosion of a metal electrode formed on the substrate can be prevented, and the heat resistance and flexibility of a primer itself can be improved.

At this time, it is preferable that the component (A) be polysilazane compound having a branched structure and the amount of the component (C) to be added be 70% by mass or more relative to the whole composition.

According to such a component (A), the heat resistance and flexibility of the primer itself can be further improved. When the component (C) is contained in an amount of 70% by mass or more, the workability of the primer composition can be improved.

It is preferable that the primer composition further contain (D) silane coupling agent.

When the primer composition contains the silane coupling agent, the adhesion of the primer composition can be further improved.

Further, the present invention provides an optical semiconductor apparatus in which a substrate mounting an optical semiconductor device and a cured material of an addition reaction curing silicone composition that encapsulates the optical semiconductor device through the primer composition.

According to such an optical semiconductor apparatus, the substrate is caused to firmly adhere to the cured material of the addition reaction curing silicone composition, and the corrosion of a metal electrode formed on the substrate can be prevented. Therefore, the optical semiconductor apparatus has high reliability.

At this time, it is preferable that the optical semiconductor device be for a light-emitting diode.

Thus, the optical semiconductor apparatus of the present invention can be suitably used for a light-emitting diode.

It is preferable that a material constituting the substrate be polyamide, ceramic, silicone, a silicone-modified polymer, or a liquid crystal polymer.

The adhesion of the primer is excellent, and therefore the optical semiconductor apparatus of the present invention can be used without detracting from the adhesion even in the substrate.

Further, it is preferable that the cured material of the addition reaction curing silicone composition be in a rubber state.

According to such a cured material of an addition reaction curing silicone composition, the firm adhesion can be achieved, and the corrosion of a metal electrode, especially an Ag electrode formed on the substrate can be effectively prevented.

According to such a primer composition of the present invention, the adhesion between a substrate mounting an optical semiconductor device and a cured material of an addition reaction curing silicone composition that encapsulates the optical semiconductor device can be improved, the corrosion of a metal electrode formed on the substrate can be prevented, and the heat resistance and flexibility of a primer itself can be improved. In addition, when the composition is used for an optical semiconductor apparatus, an optical semiconductor apparatus having a high reliability can be obtained.

### BRIEF DESCRIPTION OF THE DRAWINGS

FIG. 1: a cross-sectional view of LED lamp showing one embodiment of an optical semiconductor apparatus according to the present invention.

FIG. 2: a perspective view illustrating a test piece for an adhesion test in Examples of the present invention.

### DETAILED DESCRIPTION OF THE PREFERRED EMBODIMENTS

The present inventor carried out an extensive investigation to achieve the object, and as a result, found that when silazane compound or polysilazane compound that contains one or more silazane bonds in the molecule and an acrylic resin containing acrylate ester or methacrylate ester that contains SiH group(s) are added to a composition, brittleness that is a conventional disadvantage of the polysilazane compound can be overcome and the heat resistance that is a disadvantage of the acrylic resin can be improved. Further, the inventor found that the composition is used for adhesion between a substrate mounting an optical semiconductor device and a cured material of an addition reaction curing silicone composition that encapsulates the optical semiconductor device, to firmly adhere the substrate to the cured material, the corrosion of a metal electrode, especially an Ag electrode formed on the substrate can be prevented, and the heat resistance and flexibility of a primer film itself can be improved. Moreover, the inventor found that an optical semiconductor apparatus using the composition has a high reliability. The present invention was accomplished.

The primer composition of the present invention comprises,

(A) silazane compound(s) or polysilazane compound(s) that has one or more silazane bonds in the molecule, (B) acrylic resin(s) containing either one or both of acrylate ester(s) and methacrylate ester(s) that contains one or more SiH groups in the molecule, and (C) solvent.

Hereinafter, the respective components of the primer composition will be described.

### <Primer Composition>

### [Component (A)]

The component (A) in the primer composition of the present invention is a silazane compound or a polysilazane compound that has one or more silazane bonds in the molecule. For example, the component (A) is a component that imparts sufficient adhesion to a substrate mounting LED, especially a ceramic substrate, or a polyamide resin substrate, is used to form a very firm film, and suppresses the corrosion of a metal electrode (especially an Ag electrode) with time.

Examples of a silazane compound having one or more silazane bonds in the molecule include compounds having the following structure,

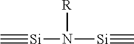

wherein R represents a hydrogen atom or a monovalent organic group.

In the formula, the monovalent organic group of R is preferably a substituted or unsubstituted monovalent hydrocarbon group having 1 to 10 carbon atoms, especially 1 to 3 carbon atoms. Examples of the monovalent hydrocarbon group include alkyl group such as methyl group, ethyl group, propyl group, isopropyl group, butyl group, isobutyl group, tert-butyl group, pentyl group, neopentyl group, hexyl group, and octyl group; cycloalkyl group such as cyclohexyl group; alkenyl group such as vinyl group, allyl group, and propenyl group; aryl group such as phenyl group, tolyl group, xylyl group, and naphthyl group; aralkyl group such as benzyl group, phenylethyl group, and phenylpropyl group; and these groups in which a part or all of the hydrogen atoms is substituted with a halogen atom such as fluorine, bromine, and chloride, a cyano group, or the like, for example, chloromethyl group, chloropropyl group, bromoethyl group, trifluoropropyl group, and cyanoethyl group. R is preferably a hydrogen atom, a methyl group, or an ethyl group, and particularly preferably a hydrogen atom.

As a polysilazane compound having one or more silazane bonds in the molecule, a polysilazane compound having a R′₂Si(NR)_{2/2} unit and/or a R′Si(NR)_{3/2} unit, wherein R is the same meanings as before and R′ is a monovalent organic group, can be used, and in particular, a polysilazane compound having a branched structure represented by a R′Si(NR)_{3/2} unit is preferable.

In the formula, examples of R′ include the same as exemplified as the substituted or unsubstituted monovalent organic group exemplified as the monovalent hydrocarbon group of R, (meth)acryloxy group-containing group such as (meth)acryloxypropyl group and (meth)acryloxymethyl group (in the present invention, “(meth)acryloxy” represents “acryloyloxy” and/or “methacryloyloxy”. The same applies hereinafter), mercapto group-containing group such as mercaptopropyl group and mercaptomethyl group, and epoxy group-containing group such as glycidoxypropyl group and glycidoxymethyl group. Among these, a (meth)acryloxy group-containing group, a mercapto group-containing group, an epoxy group-containing group, and an alkenyl group are preferable, and a (meth)acryloxy group-containing group is particularly preferable. Further, two or more kinds of different R's may be present in the molecule.

The weight average molecular weight of the polysilazane compound determined by gel permeation chromatography (GPC) measurement is preferably 200 to 10,000, more preferably 500 to 8,000, and particularly preferably 1,000 to 5,000. When the molecular weight is 200 or more, a sufficient coating strength can be obtained, and when it is 10,000 or less, the solubility in a solvent does not decrease. Thus, this range is preferable.

Specific examples of a structure of the polysilazane compound include as follows,

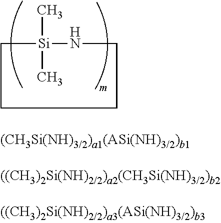

Wherein “m” represents an integer of 3 to 8; A represents a (meth)acryloxy group-containing group, a mercapto group-containing group, an epoxy group-containing group, or a vinyl group, a1 and b1 are values satisfying 0≦a1<1, 0>b1≦1, and a1+b1=1, a2 and b2 are values satisfying 0<a2<1, 0<b2<1, and a2+b2=1, and a3 and b3 are values satisfying 0≦a3<1, 0<b3≦1, and a3+b3=1.

Among examples of the polysilazane compound, a compound shown below is preferable,

(CH₃Si(Ni)_{3/2})ₐ₁(ASi(NH)_{3/2})_{b1}

wherein A, a1, and b1 represent the same meanings as before.

The component (A) can be prepared by a known method. For example, the component (A) can be prepared by reaction of ammonia gas in an excess amount relative to the molar amount of chlorine with chlorosilane having the organic group.

The amount of the component (A) to be added is not particularly restricted as long as it is such an amount that the component (A) is dissolved in the component (C) described below. It is preferably 30% by mass or less, more preferably 0.01 to 20% by mass, further preferably 0.1 to 10% by mass, and particularly preferably 0.2 to 5% by mass, relative to the whole composition (total amount of the components (A), (B), and (C)). When the component (A) is not contained, the adhesion is insufficient. When the content is 30% by mass or less, the film is not cracked by generation of irregularities on the surface, and a performance sufficient for a primer can be obtained.

### [Component (B)]

The component (B) in the primer composition of the present invention is acrylic resin containing either one or both of acrylate ester(s) and methacrylate ester(s) that contains one or more SiH groups in the molecule. For example, the component (B) imparts sufficient adhesion to a substrate mounting LED, especially a ceramic substrate, or a polyphthalamide resin substrate, a flexible film is formed on the substrate, and the corrosion of a metal electrode (especially an Ag electrode) with time is suppressed.

Examples of such an acrylic resin include a homopolymer of acrylate ester having one or more SiH groups in the molecule, a homopolymer of methacrylate ester having one or more SiH groups in the molecule, a copolymer of acrylate ester having one or more SiH groups in the molecule and methacrylate ester having one or more SiH groups in the molecule, a copolymer of acrylate ester having one or more SiH groups in the molecule and other kind of acrylate ester, and a copolymer of methacrylate ester having one or more SiH groups in the molecule and other kind of methacrylate ester.

Examples of the acrylate ester or methacrylate ester that contains one or more SiH groups in the molecule include compounds having the following structure,

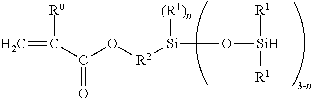

wherein R⁰ represents hydrogen atom or a methyl group, R¹ represents a monovalent organic group, R² represents a divalent organic group, and “n” represents an integer of 0 to 2.

Further, diorganopolysiloxane compounds having the following units are exemplified,

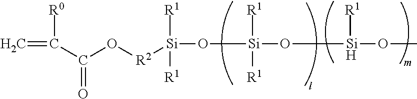

wherein “1” is a positive number including 0, and “m” is a positive number other than 0.

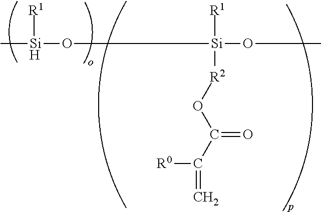

wherein “o” and “p” are positive numbers other than 0.

Examples of the other kind of acrylate ester include methyl acrylate, ethyl acrylate, n-butyl acrylate, isobutyl acrylate, isopentyl acrylate, n-hexyl acrylate, isooctyl acrylate, 2-ethylhexyl acrylate, n-octyl acrylate, isononyl acrylate, n-decyl acrylate, and isodecyl acrylate. Examples of the other kind of methacrylate ester include methyl methacrylate, ethyl methacrylate, n-butyl methacrylate, isobutyl methacrylate, isopentyl methacrylate, n-hexyl methacrylate, isooctyl methacrylate, 2-ethylhexyl methacrylate, n-octyl methacrylate, isononyl methacrylate, n-decyl methacrylate, and isodecyl methacrylate. Among these, alkyl acrylate and alkyl methacrylate that have an alkyl group having 1 to 12 carbon atoms, and particularly an alkyl group having 1 to 4 carbon atoms are preferable. The monomers may be used singly or in combination of two or more kinds.

As a method for synthesizing an acrylic resin as the component (B), a method in which the corresponding monomer is treated with a radical polymerization initiator such as 2,2′-azobisisobutyronitrile (AIBN) is exemplified.

The amount of the component (B) to be added is not particularly restricted as long as it is such an amount that the component (B) is dissolved in the component (C) described below. It is preferably 30% by mass or less, more preferably 0.01 to 20% by mass, further preferably 0.1 to 10% by mass, and particularly preferably 0.2 to 5% by mass, relative to the whole composition (total amount of the components (A), (B), and (C)). When the component (B) is not contained, the heat resistance and flexibility are not obtained. When the content is 30% by mass or less, the film is not cracked by generation of irregularities on the surface, and a performance sufficient for a primer can be obtained.

### [Component (C)]

Solvent as the component (C) is not particularly restricted as long as it is solvent in which the components (A) and (B) and an optional component described below are dissolved, and a known organic solvent can be used. Examples of the solvent include aromatic hydrocarbon-based solvent such as xylene, toluene, and benzene; aliphatic hydrocarbon-based solvent such as heptane and hexane; halogenated hydrocarbon-based solvent such as trichloroethylene, perchloroethylene, and methylene chloride; ester-based solvent such as ethyl acetate; ketone-based solvent such as methyl isobutyl ketone and methyl ethyl ketone; alcohol-based solvent such as ethanol, isopropanol, and butanol; ligroin; cyclohexanone; diethyl ether; rubber solvent; and silicone-based solvent. In particular, ethyl acetate, hexane, or acetone can be suitably used.

The components (C) may be used singly or as a mixed solvent in combination of two or more kinds depending on the evaporation rate during applying a primer.

The amount of the component (C) to be added is not particularly restricted as long as it falls within a range which does not cause difficulty to the workability during applying and drying. The amount is preferably 70% by mass or more, more preferably 80 to 99.99% by mass, further preferably 90 to 99.9% by mass, and particularly preferably 95 to 99.8% by mass, relative to the whole composition (total amount of the components (A), (B), and (C)). When the amount of the component (C) to be added is 70% by mass or more, the workability of the primer composition can be improved. For example, the substrate described below can be uniformalized during formation of a primer, the film is not cracked by generation of irregularities on the surface, and a performance sufficient for the primer can be obtained.

### [Component (D)]

The primer composition of the present invention may further contain (D) silane coupling agent. As the silane coupling agent, a general silane coupling agent can be used without particular restriction. Examples of such silane coupling agent include vinyl group-containing silane coupling agent such as vinyltrimethoxysilane and vinyltriethoxysilane; epoxy group-containing silane coupling agent such as glycidoxypropyltrimethoxysilane; (meth)acryloxy group-containing silane coupling agent such as methacryloyloxypropyltrimethoxysilane and acryloyloxypropyltrimethoxysilane; and mercapto group-containing silane coupling agent such as mercaptopropyltrimethoxysilane. Among these, vinyltrimethoxysilane and methacryloyloxypropyltrimethoxysilane are preferable.

When the component (D) is used, the amount thereof is preferably 0.05 to 10% by mass, and preferably 0.1 to 3% by mass relative to the whole composition (total amount of the components (A) to (D)). When the amount of the component (D) to be added is 0.05% by mass, an effect of improving the adhesion is sufficient. When the component (D) is added in an amount more than 10% by mass, the effect of improving the adhesion is not obtained. Therefore, it is preferable that the amount of the component (D) to be added be 10% by mass or less.

### [Other Components]

The primer composition of the present invention may contain other optional components other than the components, if necessary. For example, as metal corrosion inhibitor, benzotriazole, butyl hydroxy toluene, hydroquinone, or a derivative thereof may be added. Benzotriazole, dibutyl hydroxy toluene, hydroquinone, or a derivative thereof is a component in which the corrosion of a metal electrode, especially an Ag electrode on a substrate encapsulated with an encapsulant (cured material of addition reaction curing silicone) is effectively suppressed when LED lamp is exposed to a severe outside environment, and for example, sulfur compounds in the air permeates to the encapsulant of an optical semiconductor apparatus.

The amount of the metal corrosion inhibitor to be added is preferably 0.005 to 1 parts by mass, and particularly preferably 0.01 to 0.5 parts by mass relative to 100 parts by mass of total amount of the components (A), (B), and (C).

Further, as the other optional component, phosphor, reinforcing filler, dye, pigment, heat resistance improver, antioxidant, or adhesion promoter may be added.

### [Method for Producing Primer Composition]

As a method for producing a primer composition of the present invention, a method of uniformly mixing the components (A), (B), and (C), and if necessary, the optional component at normal temperature by a mixing stirrer is exemplified.

### <Optical Semiconductor Apparatus>

It is preferable that the optical semiconductor apparatus of the present invention be an optical semiconductor apparatus in which a substrate mounting an optical semiconductor device and a cured material of an addition reaction curing silicone composition that encapsulates the optical semiconductor device through the primer composition.

Hereinafter, an aspect of the optical semiconductor apparatus of the present invention will be described with reference to the drawings.

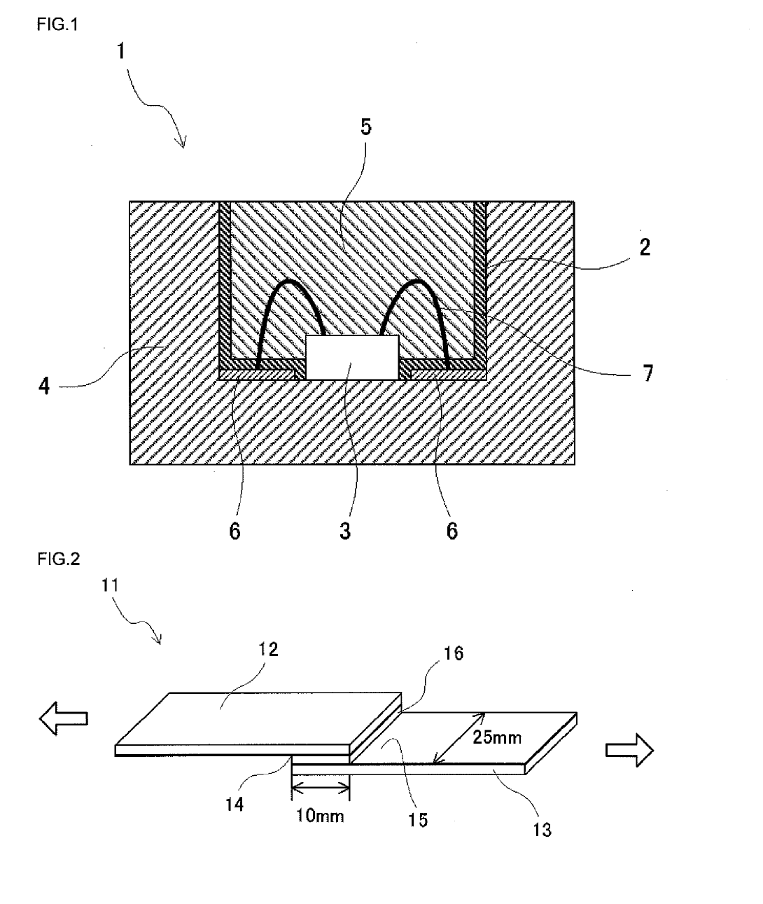

FIG. 1 is a cross-sectional view of an optical semiconductor apparatus (LED lamp) showing one example of the optical semiconductor apparatus according to the present invention. An optical semiconductor apparatus (LED) 1 is an optical semiconductor apparatus in which a substrate 4 mounting LED 3 as an optical semiconductor device and a cured material 5 of an addition reaction curing silicone composition that encapsulates the LED 3 through a primer composition 2 described above. On the substrate 4, a metal electrode 6 such as an Ag electrode is formed, an electrode terminal (not shown) of the LED 3 is electrically connected to the metal electrode 6 through a bonding wire 7.

It is preferable that a material constituting the substrate 4 be polyamide, ceramic, silicone, a silicone-modified polymer, or a liquid crystal polymer. In the present invention, in terms of good heat resistance, ceramic is more preferable, and alumina ceramic is particularly preferable. Previously, there is a problem of adhesion between a substrate formed from the material and a cured material of an addition reaction curing silicone composition as described below. As a result, separation is caused. However, when the primer composition of the present invention is used for adhesion, strong adhesion can be achieved without delaminating. Therefore, an optical semiconductor apparatus can be produced using the material having good mechanical strength and heat resistance for a substrate.

The cured material of an addition reaction curing silicone composition 5 is obtained by curing an addition reaction curing silicone composition, and is preferably a transparent cured material and in a rubber state. As the addition reaction curing silicone composition, a composition having an organopolysiloxane compound having a known vinyl group, organohydrogenpolysiloxane that is a crosslinker, and a platinum-based catalyst that is an addition reaction catalyst can be used. Further, as the other optional component, reaction inhibitor, colorant, flame retardant-imparting agent, heat resistance improver, plasticizer, reinforcing silica, adhesion-imparting agent, or the like may be added to the silicone composition.

As a method for producing the optical semiconductor apparatus (LED lamp) 1 shown in FIG. 1, the following method is exemplified.

The metal electrode 6 such as an Ag electrode is formed in advance by Ag plating on the substrate 4, an optical semiconductor device such as the LED 3 is adhered to the substrate 4 through an adhesive, and the electrode terminal (not shown) of the LED 3 is electrically connected to the metal electrode 6 through the bonding wire 7. After then, the substrate 4 mounting the LED 3 is cleaned, if necessary. The primer composition 2 was applied to the substrate 4 by an application apparatus such as a spinner or a sprayer, and a solvent in the primer composition 2 is volatilized by heating or air-drying. A coating having a thickness of preferably 10 μm or less, and more preferably 0.1 to 5 μm is formed. After the formation of the coating of the primer, an addition reaction curing silicone composition is applied by a dispenser or the like, followed by standing at room temperature or heating, and is cured to encapsulate the LED 3 with a rubber cured material 5.

As described above, when the primer composition of the present invention that contains the components (A), (B), and (C) is used, the substrate mounting the optical semiconductor device such as the LED is caused to firmly adhere to the cured material of the addition reaction curing silicone composition. Therefore, an optical semiconductor apparatus having a high reliability, especially LED lamp can be provided.

Even when the LED lamp is exposed to a severe outside environment and a sulfur compound, or the like, in the air permeates the cured material of the silicone composition, the use of the primer composition can suppress the corrosion of the metal electrode, especially the Ag electrode on the substrate.

The optical semiconductor apparatus of the present invention can be suitably used for LED. The aspect is described by using an optical semiconductor apparatus for LED as one example of the optical semiconductor device. In addition, the optical semiconductor apparatus can be applied to a phototransistor, a photodiode, CCD, a photovoltaic module, EPROM, a photocoupler, or the like.

### EXAMPLES

In the following, the present invention will be explained specifically by Synthesis Examples, Examples, and Comparative Examples, but the present invention is not restricted to the following Examples.

### Synthesis Example 1

### Synthesis of Polysilazane Compound

A 2-L four necked flask equipped with a graham condenser and a thermometer was charged with 1,000 g of ethyl acetate, and then charged with 3.8 g of methacryloyloxypropyl trichlorosilane (0.015 mol) and 41.5 g of methyltrichlorosilane (0.28 mol). The mixture was stirred in an ice bath. When the temperature in the system was 10° C. or lower, 15 g of ammonia gas (0.89 mol) was blown. After the blowing, the mixture was stirred for 3 hours. After completion of stirring, ammonium chloride as a by-product was filtered off to obtain a 4% by mass solution of ethyl acetate in polysilazane.

The synthesized polysilazane compound was measured by ²⁹Si-NMR and ¹H-NMR. The structure of the polysilazane was as follows. The weight average molecular weight measured by GPC (THF solvent) was 2,000.

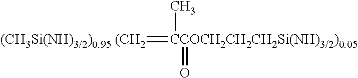

### Synthesis Example 2

### Synthesis of Polysilazane Compound

A 2-L four necked flask equipped with a graham condenser and a thermometer was charged with 1,000 g of ethyl acetate, and then charged with 19 g of dimethylchlorosilane (0.15 mol) and 22.5 g of methyltrichlorosilane (0.15 mol). The mixture was stirred in an ice bath. When the temperature in the system was 10° C. or lower, 14 g of ammonia gas (0.83 mol) was blown. After the blowing, the mixture was stirred for 3 hours. After completion of stirring, ammonium chloride as a by-product was filtered off to obtain a 4% by mass solution of ethyl acetate in polysilazane.

The synthesized polysilazane compound was measured by ²⁹Si-NMR and ¹H-NMR. The structure of the polysilazane was as follows. The weight average molecular weight measured by GPC (THF solvent) was 2,000.

(CH₃)₂Si(NH)_{2/2})_{0.5}(CH₃Si(NH)_{3/2})_{0.5}

### Synthesis Example 3

### Synthesis of SiH Group-Containing Methacrylate Ester

A 500-mL four necked flask equipped with a graham condenser and a thermometer was charged with 124 g of methacryloxypropylmethyldimethoxysilane (0.5 mol) and 107 g of 1,1,3,3-tetramethyldisiloxane (0.8 mol), and the mixture was cooled to 10° C. or lower by an ice bath. After the cooling, 13.7 g of concentrated sulfuric acid was added and mixed for 20 minutes. After the mixing, 14.4 g of water (0.75 mol) was added dropwise to perform hydrolysis equilibration reaction. After completion of the reaction, 4.5 g of water was added to separate waste acid. 250 g of 10% mirabilite solution and 220 g of toluene were added followed by washing with water, to remove an acid catalyst component. After the removing, the solvent was removed by condensation at 50° C./5 mmHg, to yield 152 g of SiH group-containing methacrylate ester having the following structure.

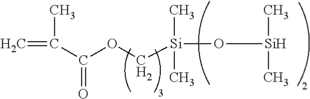

### Synthesis Example 4

### Synthesis of SiH Group-Containing Methacrylate Ester

355 g of octamethyl cyclotetrasiloxane (1.2 mol), 289 g of 1,3,5,7-tetramethyl cyclotetrasiloxane (1.2 mol), 39.7 g of dimethacryloxypropyl tetramethyldisiloxane (0.12 mol), 22.3 g of divinyl tetramethyldisiloxane (0.12 mol), 2 g of methanesulfonic acid (amount of catalyst) were placed in a 1-L four necked flask equipped with a graham condenser and a thermometer, heated to 60 to 70° C., and mixed for 6 hours. After the mixing, the temperature was cooled to room temperature, and 24 g of baking soda was added to neutralize the mixture. After the neutralization, the mixture was filtered, the filtrate was condensed at 100° C./5 mmHg, to remove an unreacted component. Thus, 408 g of SiH group-containing methacrylate ester having the following structure was obtained.

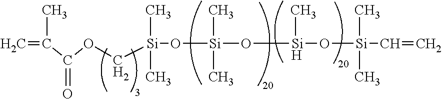

### Synthesis Example 5

### Synthesis Example of SiH Group-Containing Methacrylate Ester Polymer

43 Parts by mass of methyl methacrylate, 22 parts by mass of SiH group-containing methacrylate ester prepared in Synthesis Example 3, 600 parts by mass of mixed solvent of isopropyl alcohol (IPA) and ethyl acetate, and 0.5 parts by mass of 2,2′-azobisisobutyronitrile (AIBN) were heated and stirred at 80° C. for 3 hours to adjust a solution containing an SiH group-containing methacrylate ester polymer.

### Synthesis Example 6

### Synthesis Example of SiH Group-Containing Methacrylate Ester Polymer

57 Parts by mass of methyl methacrylate, 24 parts by mass of SiH group-containing methacrylate ester prepared in Synthesis Example 4, 600 parts by mass of ethyl acetate, and 0.5 parts by mass of 2,2′-azobisisobutyronitrile (AIBN) were heated and stirred at 80° C. for 3 hours to adjust a solution containing an SiH group-containing methacrylate ester polymer.

### Comparative Synthesis Example 1

100 Parts by mass of methyl methacrylate, 900 parts by mass of ethyl acetate, and 0.5 parts by mass of 2,2′-azobisisobutyronitrile (AIBN) were heated and stirred at 80° C. for 3 hours to prepare a solution containing a methyl methacrylate polymer.

83 Parts by mass of methyl methacrylate, 17 parts by mass of γ-methacryloyloxypropyl trimethoxysilane, 900 parts by mass of ethyl acetate, and 0.5 parts by mass of 2,2′-azobisisobutyronitrile (AIBN) were heated and stirred at 80° C. for 3 hours to prepare a solution containing a methyl methacrylate polymer.

### Example 1

50 Parts by mass of SiH group-containing methacrylate ester polymer prepared in Synthesis Example 5, 1.5 parts by mass of vinyltrimethoxysilane, and 0.15 parts by mass of hydroquinone were added to 100 parts by mass of solution of polysilazane compound prepared in Synthesis Example 1 in ethyl acetate, and the mixture was stirred to obtain a primer composition.

An optical semiconductor apparatus was produced using the obtained primer composition. Various physical properties (external appearance, transmissivity, adhesion (adhesion strength), and corrosion resistance) were measured by evaluation methods shown below. The results are shown in Table 1. The physical properties shown in Table 1 are values measured at 23° C.

### [External Appearance]

The resulting primer composition was applied to an alumina ceramic plate by a brush so that the thickness was 2 μm, allowed to stand at 23° C. for 30 minutes, dried, and subjected to drying treatment at 150° C. for 30 minutes. An addition reaction curing silicone rubber composition (available from Shin-Etsu Chemical Co., Ltd., KER-2700) was applied to the primer composition so that the thickness was 2 mm, and then cured at 150° C. for 1 hour. The external appearance was observed.

### [Transmissivity Test]

The resulting primer composition was applied to a glass slide by a brush so that the thickness was 2 μm, and allowed to stand at 23° C. for 30 minutes, and dried. Thus, a primer composition coating was formed. The transmissivity of the glass slide on which the primer composition coating was formed at a wavelength of 400 nm was measured by using the air as a blank. The heat resistance of the glass slide on which the primer composition coating was formed was deteriorated by 150° C.×1,000 hours. This transmissivity was measured in the same manner as described above.

### [Adhesion (Adhesion Strength) Test]

A test piece 11 for an adhesion test as shown in FIG. 2 was produced. The resulting primer composition was applied to one side of each of two alumina ceramic substrates 12 and 13 (available from KDS Co., Ltd., width: 25 mm) so that the thickness was 0.01 mm, allowed to stand at 23° C. for 60 minutes, and dried. Thus, primer composition coatings 14 and 15 were formed. The alumina ceramic substrates were disposed so that the faces forming the primer composition coatings 14 and 15 were opposite to each other and edges thereof were overlapped by 10 mm. An addition reaction curing silicone rubber composition (available from Shin-Etsu Chemical Co., Ltd., KER-2700) in a thickness of 1 mm was sandwiched between the substrates, and cured by heating at 150° C. for 2 hours. The substrates adhered to each other through a cured material 16 of the silicone rubber composition (adhesion area: 25 mm×10 mm=250 mm²), to produce a test piece including the two alumina ceramic substrates.

The edge of each of the alumina ceramic substrates 12 and 13 of the test piece was drawn in opposite directions (arrow directions in FIG. 2) by a tensile tester (manufactured by Shimadzu Corporation, Autograph) at a tensile rate of 50 mm/min. The adhesion strength (MPa) per unit area was determined.

### [Corrosion Test]

The resulting primer composition was applied to a silver-plated plate by a brush so that the thickness was 2 μm, allowed to stand at 23° C. for 30 minutes, and dried. An addition reaction curing silicone rubber composition (available from Shin-Etsu Chemical Co., Ltd., KER-2700) was applied to the primer composition so that the thickness was 1 mm, and then cured at 150° C. for 1 hour. A test piece having a silicone rubber layer was produced. The test piece and 0.1 g of sulfur crystal were placed in a 100-cc glass bottle. The glass bottle was encapsulated, and allowed to stand at 70° C. One day later, eight days later, and 12 days later, the silicone rubber layer of the test piece was separated. A degree of corrosion of a part where the silicone rubber layer of the silver-plated plate was separated was visually observed and evaluated by the following criteria.

∘: No corrosion (discoloration)

x: Blacking

### Example 2

A mixture in which 100 parts by mass of SiH group-containing methacrylate ester polymer prepared in Synthesis Example 6 was added to 100 parts by mass of solution of polysilazane compound prepared in Synthesis Example 2 in ethyl acetate was used as it was, and a primer composition was obtained. An optical semiconductor apparatus was produced using this composition. Various physical properties were measured in the same manner as in Example 1. The results are shown in Table 1.

### Comparative Example 1

A primer composition was not applied and an addition reaction curing silicone rubber composition (available from Shin-Etsu Chemical Co., Ltd., KER-2700) was directly applied to an alumina ceramic plate and a silver-plated plate, and cured. The adhesion and corrosion resistance of an optical semiconductor apparatus thus formed were measured in the same manner as in Example 1. The results are shown in Table 1.

### Comparative Example 2

1 part by mass of vinyltrimethoxysilane and 0.1 parts by mass of hydroquinone were added to 100 parts by mass of solution of methyl methacrylate ester polymer prepared in Comparative Synthesis Example 1 in ethyl acetate, and the mixture was stirred to obtain a primer composition. An optical semiconductor apparatus was produced using this composition. Various physical properties were measured in the same manner as in Example 1. The results are shown in Table 1.

### Comparative Example 3

1 part by mass of γ-glycidoxypropyltrimethoxysilane and 1 part by mass of tetra-n-butyltitanate were added to 100 parts by mass of solution of methyl methacrylate ester polymer prepared in Synthesis Comparative Example 1 in ethyl acetate, and the mixture was stirred to obtain a primer composition. An optical semiconductor apparatus was produced using this composition. Various physical properties were measured in the same manner as in Example 1. The results are shown in Table 1.

### Comparative Example 4

An optical semiconductor apparatus was produced using a solution of polysilazane compound prepared in Synthesis Example 1 in ethyl acetate. Various physical properties were measured in the same manner as in Example 1. The results are shown in Table 2.

### Comparative Example 5

An optical semiconductor apparatus was produced using 100 parts by mass of solution of SiH group-containing methacrylate ester polymer prepared in Synthesis Example 5 in ethyl acetate. Various physical properties were measured in the same manner as in Example 5. The results are shown in Table 2.

TABLE 1

| | | | | Comparative | Comparative | Comparative |
|---|---|---|---|---|---|---|
| | | Example 1 | Example 2 | Example 1 | Example 2 | Example 3 |
| External | | Colorless | Colorless | Not | Colorless | Pale yellow |
| appearance of | | and | and | applying | and | and |
| primer film | | transparent | transparent | | transparent | transparent |
| Transmissivity | Early | 91 | 92 | — | 80 | 85 |
| (%) | stage | | | | | |
| | after | 90 | 92 | — | Crack | Crack |
| | 150° C. × | | | | | |
| | 1000 | | | | | |
| | hours | | | | | |
| Adhesion | Alumina | 2.7 | 2.6 | 1.2 | 1.5 | 1.5 |
| (MPa) | ceramic | | | | | |
| Corrosion | 1 day | ∘ | ∘ | x | x | ∘ |
| resistance | later | | | | | |
| | 8 days | ∘ | ∘ | | | ∘ |
| | later | | | | | |
| | 12 days | ∘ | ∘ | | | x |
| | later | | | | | |

TABLE 2

| | Comparative | Comparative |
|---|---|---|
| | Example 4 | Example 5 |
| External | Colorless | Colorless |
| appearance | and | and |
| of primer | transparent | transparent |
| film | | |

| | | | |
|---|---|---|---|
| Transmissivity | Early | 80 | 92 |
| (%) | stage | | |
| | after | Crack | 85 |
| | 150° C. × | | |
| | 1000 | | |
| | hours | | |
| Adhesion | Alumina | 2.8 | 1.8 |
| (MPa) | ceramic | | |
| Corrosion | 1 day | ∘ | ∘ |
| resistance | later | | |
| | 8 days | ∘ | ∘ |
| | later | | |
| | 12 days | ∘ | ∘ |
| | later | | |

As apparent from the results of Table 1, in Examples 1 and 2 using the primer composition which contains a polysilazane compound and a SiH group-containing methacrylate ester polymer, the alumina ceramic is caused to firmly adhere to the rubber cured material of the addition reaction curing silicone rubber composition. Further, in the heat resistance test of a primer composition coating applied to a glass slide, discoloration does not occur, the coating itself is not changed, and the heat resistance is excellent. In the corrosion test using a silver-plated plate instead of alumina ceramic in Examples 1 and 2, discoloration after one day does not occur, and an effect of suppressing discoloration (corrosion) after 12 days appears.

On the other hand, as apparent from the results of Table 1, in Comparative Example 1 not forming a primer, the adhesion is not sufficient, and the corrosion after one day appears in the corrosion test. In Comparative Examples 2 and 3 using a primer composition which contains a methyl methacrylate ester polymer which does not contain a SiH group instead of the component (B), the heat resistance, the adhesion, and the corrosion resistance are low.

As apparent from the results of Table 2, in Comparative Example 4 using a primer composition which does not contain the component (B), the adhesion and the corrosion resistance are good, but the heat resistance is low. In Comparative Example 5 using a primer composition which does not contain the component (A), the corrosion resistance is good, but change in the heat resistance with time appears and the adhesion is not sufficient.

As apparent from the results, according to the primer composition of the present invention, the adhesion between a substrate mounting an optical semiconductor device and a cured material of an addition reaction curing silicone composition that encapsulates the optical semiconductor device can be improved, the corrosion of a metal electrode on the substrate can be prevented, and the heat resistance of a primer can be improved.

The present invention is not restricted to the embodiments shown above. The embodiments are merely examples so that any embodiments composed of substantially the same technical concept as disclosed in the claims of the present invention and expressing a similar effect are included in the technical scope of the present invention.

What is claimed is:

1. A primer composition which adheres a substrate mounting an optical semiconductor device and a cured material of an addition reaction curing silicone composition that encapsulates the optical semiconductor device, comprising: (A) silazane compound or polysilazane compound that has one or more silazane bonds in the molecule; (B) acrylic resin containing either one or both of acrylate ester and methacrylate ester that contains one or more SiH groups in the molecule; and (C) solvent.

2. The primer composition according to claim 1, wherein the component (A) is polysilazane compound having a branched structure and an amount of the component (C) to be added is 70% by mass or more relative to the whole composition.

3. The primer composition according to claim 1, further comprising (D) silane coupling agent.

4. The primer composition according to claim 2, further comprising (D) silane coupling agent.

5. An optical semiconductor apparatus produced by adhering a substrate mounting an optical semiconductor device and a cured material of an addition reaction curing silicone composition that encapsulates the optical semiconductor device through the primer composition according to claim 1.

6. An optical semiconductor apparatus produced by adhering a substrate mounting an optical semiconductor device and a cured material of an addition reaction curing silicone composition that encapsulates the optical semiconductor device through the primer composition according to claim 2.

7. An optical semiconductor apparatus produced by adhering a substrate mounting an optical semiconductor device and a cured material of an addition reaction curing silicone composition that encapsulates the optical semiconductor device through the primer composition according to claim 3.

8. An optical semiconductor apparatus produced by adhering a substrate mounting an optical semiconductor device and a cured material of an addition reaction curing silicone composition that encapsulates the optical semiconductor device through the primer composition according to claim 4.

9. The optical semiconductor apparatus according to claim 5, wherein the optical semiconductor device is for a light-emitting diode.

10. The optical semiconductor apparatus according to claim 6, wherein the optical semiconductor device is for a light-emitting diode.

11. The optical semiconductor apparatus according to claim 7, wherein the optical semiconductor device is for a light-emitting diode.

12. The optical semiconductor apparatus according to claim 8, wherein the optical semiconductor device is for a light-emitting diode.

13. The optical semiconductor apparatus according to claim 5, wherein a material constituting the substrate is any one of polyamide, ceramic, silicone, a silicone-modified polymer, and a liquid crystal polymer.

14. The optical semiconductor apparatus according to claim 6, wherein a material constituting the substrate is any one of polyamide, ceramic, silicone, a silicone-modified polymer, and a liquid crystal polymer.

15. The optical semiconductor apparatus according to claim 7, wherein a material constituting the substrate is any one of polyamide, ceramic, silicone, a silicone-modified polymer, and a liquid crystal polymer.

16. The optical semiconductor apparatus according to claim 8, wherein a material constituting the substrate is any one of polyamide, ceramic, silicone, a silicone-modified polymer, and a liquid crystal polymer.

17. The optical semiconductor apparatus according to claim 5, wherein the cured material of the addition reaction curing silicone composition is in a rubber state.

18. The optical semiconductor apparatus according to claim 6, wherein the cured material of the addition reaction curing silicone composition is in a rubber state.

19. The optical semiconductor apparatus according to claim 7, wherein the cured material of the addition reaction curing silicone composition is in a rubber state.

20. The optical semiconductor apparatus according to claim 8, wherein the cured material of the addition reaction curing silicone composition is in a rubber state.
